(19) United States
(12) Patent Application Publication
(10) Pub. No.: US 2007/0114616 A1
(43) Pub. Date: May 24, 2007

(54) Field effect transistor and method of manufacturing the same

(76) Inventors: Dirk Manger, Dresden (DE); Till Schloesser, Dresden (DE)

Correspondence Address: SLATER & MATSIL LLP, 17950 PRESTON ROAD, SUITE 1000, DALLAS, TX, 75252, US

(21) Appl. No.: 11/287,151

(22) Filed: Nov. 23, 2005

(51) Int. Cl. H01L 29/76

(52) U.S. Cl. 257/407

(57) ABSTRACT

A field effect transistor, which is arranged in a semiconductor device, comprises a first and a second doped source/drain region, both regions being arranged within a semiconductor substrate on either side of a gate electrode, and a channel region formed within the substrate between both doped source/drain regions beneath said gate electrode. A gate oxide layer is formed upon the semiconductor substrate. The gate electrode contacts a surface of the gate oxide layer and further comprises at least a first and a second conductive layer, wherein the first and second conductive layers are made of materials having different work functions with respect to each other. The first conductive layer contacts the gate oxide layer within a first portion of the surface, and the second conductive layer contacts the gate oxide layer within a second portion of the surface. The first conductive layer is further conductively connected to the second conductive layer.

### TECHNICAL FIELD

The invention generally relates to a field effect transistor formed in or on a semiconductor substrate and to a method of manufacturing the field effect transistor. The invention particularly relates to field effect transistors provided in small pitch integrated circuits and/or in DRAM memory devices.

### BACKGROUND

In the field of manufacturing semiconductor devices, particularly DRAM devices (dynamic random access memory), pitches and line widths are continuously decreased in order to improve the integration level of the devices. With regard to field effect transistors generally formed with the semiconductor devices this decrease of dimensions poses several problems when considering the electrical characteristics to be maintained. When entering a sub-em linewidth regime, leakage current effects between gate, source, drain and/or well become important contributors to deficiencies inherent in an integrated circuit.

Accordingly, when designing an integrated circuit these effects have to be considered by adapting corresponding supply voltages, retaining minimum lateral dimensions or layer thicknesses (e.g., of the gate oxide) or applying appropriate doping levels, etc., with respect to the components of a respective transistor. However, continued shrinking of the dimensions will inevitably lead to physical limits as the maximum allowable leakage current will further be reduced. In the case of DRAM memories, where currents or charges being trapped in a conductive filling of a storage node are used to store the information, undesired loss of currents necessitates a more frequent refresh operation of the stored current thus counteracting the gain in speed due to the shrinking process.

Different mechanisms related to leakage currents are known and well studied, such as junction leakage, gate-induced drain leakage (GIDL) and drain-induced barrier lowering (DIBL), etc.

Junction leakage has its origin in minority carrier diffusion and drift near edges of depletion regions (also referred to as channel region throughout this document) of a transistor. Electron hole pair generation may further be responsible for this kind of leakage. Additionally, in the case of heavily doped source/drain regions, band-to-band tunneling may occur.

Gate-induced drain leakage (GIDL) has its origin in the strong field generated under certain circumstances near the drain junction. In case of, e.g., an n-channel field effect transistor (N-MOSFET) the gate voltage may be biased, in order to drive the transistor sufficiently below the threshold voltage (transistor off, at 0.0 V or below). As a result, holes accumulate in the depletion surface region below the gate electrode adjacent to the gate oxide layer thereby forming a channel region, which now acts as a highly doped p-type region within a moderately doped p-type well (substrate), while both the substrate and the channel hold the same bias potential. A strong field is then generated, if the n-type drain region is simultaneously connected to the supply voltage. Minority charge carriers and band-to-band tunneling then lead to a current from n-type drain to p-type well (substrate).

Drain-induced barrier lowering (DIBL) occurs when a high drain voltage is applied to a transistor having a particularly short channel. The profile of voltage potential along the channel is affected and carriers are injected from the source region towards the channel surface adjacent to the gate oxide layer. The channel width is narrowed, which again may influence the effective threshold voltage of the field effect transistor.

Gate-induced drain leakage (GIDL) mainly limits the minimum thickness of the gate oxide layer and the voltage supply to source/drain, while drain-induced barrier lowering (DIBL) limits the channel width.

With regard to the gate-induced drain leakage (GIDL), US Patent Publication No. 2003/0094651 A1, published May 22, 2003, a proposed field effect transistor has a primary gate electrode assisted by an auxiliary electrode formed as a spacer adjacent to an oxide film, which isolates both electrodes from each other, respectively. The primary electrode contacts a gate oxide formed on a substrate, while the auxiliary electrode contacts said oxide film, which is arranged between the auxiliary electrode and each of the source/drain regions of the transistor. Both electrodes are independently supplied with their own voltage sources, respectively.

In operation, when the primary gate electrode is biased to 0.0 V upon a refresh of a DRAM, the auxiliary electrode is simultaneously supplied with the same voltage as the underlying source/drain region in order to suppress the occurrence of a GIDL current.

### SUMMARY OF THE INVENTION

One aspect of the invention improves the electrical characteristics of an NMOS or PMOS field effect transistor. In particular, an aspect of the invention reduces leakage currents between source/drain, gate and well/substrate of a transistor formed in a semiconductor device.

These and other benefits are obtained by a field effect transistor formed in a semiconductor substrate, comprising a first and a second doped source/drain region, both regions arranged within the substrate on either side of a gate electrode, a channel region formed within the substrate between both doped source/drain regions beneath the gate electrode, a gate oxide layer formed upon the semiconductor substrate, the gate electrode, which contacts a surface of the gate oxide layer and which further comprises at least a first and a second conductive layer, the first and second conductive layers being made of materials having different work functions with respect to each other. The first conductive layer of the gate electrode contacts the gate oxide layer within a first portion of the surface, the second conductive layer contacts the gate oxide layer within a second portion of the surface, and the first conductive layer is further conductively connected to the second conductive layer.

In a preferred embodiment, a field effect transistor (FET) is provided, which may be an n-channel MOSFET or a p-channel MOSFET. The transistor comprises a gate electrode, a first and a second source/drain region, a channel region arranged between the source/drain regions, and a gate dielectric layer, e.g., a gate oxide.

The gate electrode comprises a first conductive layer as well as a second conductive layer. Both conductive layers simultaneously contact the gate dielectric layer in respective first and second portions of a surface of that layer. Both portions, the first and the second portion, preferably overlap with the channel region in order to affect its electrical characteristics during operation.

The material selected each for the first and second conductive layers, respectively, differs in that the work function, i.e., the energy difference needed to extract an electron from the material to vacuum, is not the same with respect to both layers. Accordingly, the materials selected for the layers relate to different chemical elements or compounds, or alternatively to similar elements or compounds, which, however, have been modified by, e.g., different types of doping, etc., in order to yield distinct conductor characteristics.

Further, the first and the second conductive layers are (electrically) conductively connected with each other. This connection is permanent, i.e., the conductive connection between both layers is not only provided by means of a remote circuit on specific occasions. Rather, the connection is provided within the same transistor by means of a direct or an indirect contact between both layers. According to one embodiment, the conductive connection is provided via a third conductive layer, which may be arranged on top of one of the first or second conductive layers. The third layer may comprise the same or a different chemical composition as one of the first or second conductive layers.

As a consequence of this configuration, the gate contact area on top of the gate dielectric layer is established by two different conductive layers, which—when being connected to the same power or voltage supply as these are conductively connected—exhibit different work functions at the same voltage potential. This portioned gate contact area adversely affects the electrical characteristics at the surface of the channel region on the opposite side of the gate dielectric layer. However, varying the work function acts on the depletion region below as if the voltage potential of the same layer has been changed. As a result, the profile of the depletion or accumulation characteristic along the length direction of the channel region changes according to the work function of the material chosen for the two conductive layers, respectively.

In one embodiment, n-doped or p-doped poly silicon is employed for the first layer. In a further embodiment the second conductive layer may be a material selected from a group of so-called midgap materials. These materials are characterized by moderate values of the work function. However, as there are varying definitions available for midgap materials, a range of work functions provided for this specific embodiment may have a minimum value of 4.4 eV and a maximum value of 4.9 eV. It is noted that the invention is not limited to any of such ranges provided herein or in other literature.

According to another definition of midgap materials, the work function of the midgap materials is larger than that of materials that are similar to heavily n-doped poly silicon, and is smaller than materials that are similar to heavily p-doped poly silicon.

Examples of suitable midgap materials are tungsten (W), titanium nitride (TiN), tungsten silicide (WSi_{X}), nitrogen implanted molybdenum (Mo(N)) and tantalum nitride. However, it is noted that the invention is not limited thereto.

According to another embodiment, the second conductive layer is formed as a vertical spacer at a sidewall of a gate stack, which comprises the first conductive layer. The effect is that the second conductive layer has a reduced footprint with regard to its portion of the gate contact area, and the overall characteristics are dominated by the first conductive layer, which has a larger footprint. A suitable material may be chosen, therefore, in order to set the threshold value. Nevertheless, as the vertical spacer of the second conductive layer is located near the drain/well junction, its work function may, according to the specific design, be selected to reduce leakage effects particularly in that region, despite its small footprint. The occurrence of strong fields near the junctions may thus be mitigated.

A further advantage of the vertical spacer is that, due to its small footprint, the dimension of the gate electrode is not considerably increased.

In case a horizontal layer in a gate stack is formed with respect to the first conductive layer and a vertical spacer is formed at a gate stack sidewall with respect to the second conductive layer, and in case an n- or p-doped poly silicon as well as a midgap material is chosen for the respective conductive layers, advantageous embodiments of the invention relate to both possibilities that the midgap material is selected either for the first or the second conductive layer.

Preferred embodiments of the invention become particularly advantageous with respect to DRAM memory devices. Herein, a specific need for further shrinking exists. Further, it has been found that a drain region suffers from leakage currents only on a single side of the transistor—the drain connected to the bit line.

According to an embodiment of the invention, a single-sided vertical conductive spacer is arranged with respect to this drain region, which is that region connected to a voltage supply, e.g., a bit line.

The complementary source region may be—according to still a further embodiment—connected to a storage node. The storage node according to this embodiment may reside in a trench capacitor or in a stacked capacitor.

Another aspect of the invention is a method of manufacturing a field effect transistor in a semiconductor substrate, comprising providing the semiconductor substrate, depositing a gate dielectric layer on the semiconductor substrate, forming a first conductive layer of a material having a first work function upon the gate dielectric layer, depositing an isolating capping layer, etching the first conductive layer and the isolating capping layer to form a gate stack upon the gate dielectric layer, depositing a second conductive layer of a material having a second work function different from the first work function on a sidewall of the etched gate stack and on the gate dielectric layer to form a conductive vertical spacer, the spacer and the gate stack forming a gate electrode, and implanting the semiconductor substrate where it is not shielded by the gate stack and the vertical conductive spacer to form first and second source/drain regions.

Further advantageous aspects and embodiments are evident from the appended claims.

### BRIEF DESCRIPTION OF THE DRAWINGS

Other objects and many of the attendant advantages of embodiments of the present invention will be readily appreciated and become better understood by reference to the following more detailed description of preferred embodiments in connection with the accompanied drawings. Features that are substantially or functionally equal or similar will be referred to with the same reference signs.

FIGS. 1-4 illustrate side views of a MOSFET according to various embodiments of the present invention;

FIG. 5 shows a flow chart illustrating the steps of a method of manufacturing a MOSFET according to an embodiment of the invention; and

FIGS. 6-7 show details of step 92 in FIG. 5 according to further alternative embodiments of the present invention.

The following list of reference symbols can be used in conjunction with the figures:

1 MOSFET 28 source/drain regions

4 gate electrode 30 LDD

10, 102, 104, 106 1^{st} conductive layer 32, 322, 323 isolation spacer

12, 122, 124, 126 2^{nd} conductive layer 38 sidewall of gate stack

14 3^{rd} conductive layer 40, 42 portions of gate contact area

16 capping layer 50 electrically conductive connection

18 sidewall oxidation layer 500 voltage supply

20, 202, 204, 206 nitride liner 70 storage node

22 gate dielectric layer 75 sense amplifier

24 semiconductor substrate 80-100, 922, 924, 926 method steps

26 channel region, depletion region

### DETAILED DESCRIPTION OF ILLUSTRATIVE EMBODIMENTS

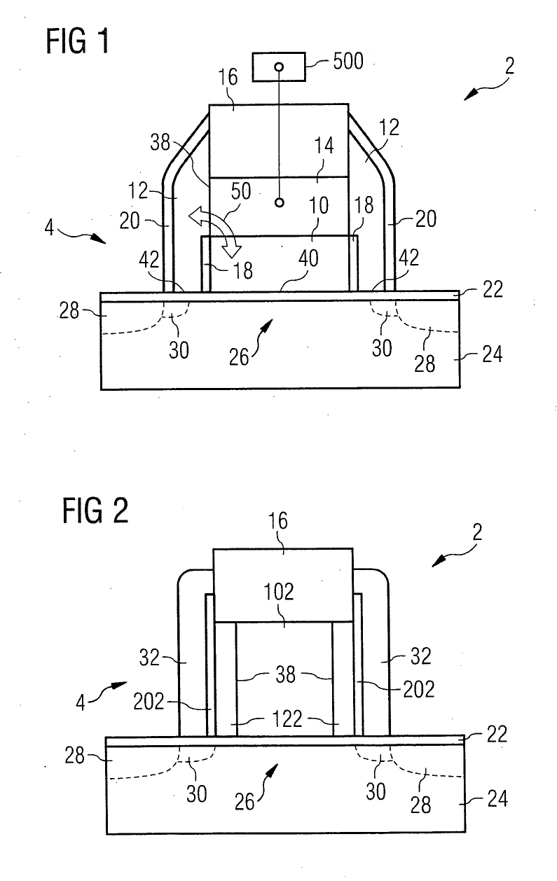

FIG. 1 shows a first embodiment of a MOSFET 2 according to the present invention. A gate electrode 4 is arranged on a gate dielectric layer 22, which may be a gate oxide. Other dielectric materials such as a nitride may be suitable as well. The gate dielectric layer 22 according to this embodiment has a thickness of, e.g., 10 nm and is formed by oxidation of a surface of a semiconductor substrate 24, which is made of monocrystalline silicon.

The gate electrode 4 comprises a gate stack with a sequence of layers 10, 14, 16—from bottom to top—starting with n-doped poly silicon (first conductive layer 10), tungsten silicide (third conductive layer 14) and silicon nitride (isolating capping layer 16). The first conductive layer 10 of poly silicon provides the actual gate electrode, while the third conductive layer 14 of tungsten silicide provides for a conductor having a low ohmic resistance, which may further serve, e.g., as a word line in a DRAM. The third conductor 14 is coupled to a voltage supply 500 selectively providing levels of a voltage potential.

The gate stack has sidewalls 38. A portion of the sidewalls 38 provided by the lowermost first conductive layer 10 of poly silicon is covered with a sidewall oxidation layer 18. Further, a vertical spacer formed by a second conductive layer 12 of a midgap material such as tungsten or tungsten silicide is arranged adjacent to both sidewalls 38 of the gate stack. A nitride liner 20 covers the vertical spacers on both sides of the gate electrode 4. As indicated by arrow 50, an electrical connection is established between the first 10 and the second 12 conductive layers via the third conductive layer 14.

The first conductive layer 10 of poly silicon is doped to have a work function of 4.1 eV, and the second conductive layer of tungsten, or tungsten silicide has a work function of 4.6 eV, or 4.7 eV respectively—with respect to vacuum.

The gate electrode 4 has a device length of 90 nm, of which 65-70 nm are contributed by the extension of the first conductive layer 10, and 10 nm are provided by each of the two vertical spacers on either side of the gate stack. A surface 40, or gate contact area is divided into a first portion 40 provided by the footprint of the first conductive layer 10, and into a second portion(s) 42 provided by the footprint of the second conductive layer 12, i.e., the vertical spacer shown in FIG. 1. It is noted that the invention is not limited to the dimensions provided according to this embodiment.

Within substrate 24, first and second highly n-doped source/drain regions 28 are each formed by means of implantation. Lightly n-doped drains 30 (LDD) absorb strong field gradients with respect to a p-type channel region (well) with respect to the source/drain regions 28.

The reduction of field gradients due to the LDDs is further supported by portions 42 due to the second conductive layer. As the work function is larger in this case, accumulation of holes near the surface of the depletion or channel region 26 is reduced when the voltage of the gate electrode 4 has dropped to 0.0 V or below near the junction edges of the depletion region.

Source/drain regions 28 will occasionally—and depending on the design of the circuit—be connected with conductive contacts, which are not shown here for simplicity and to illustrate the principles of embodiments according to the invention.

Referring now to FIG. 2, which shows a second alternative embodiment of a MOSFET 2, the gate electrode 4 comprises a first conductive layer 102 of p-doped poly silicon, which extends in vertical direction to the isolating capping layer 16. In this example the gate stack is formed solely by the first layer 102, i.e., no third conductive layer is needed. Vertical spacers are formed by a second conductive layer 122 adjacent to the sidewalls 38 of the gate stack. The second conductive layer 122 is arranged in a two-sided manner with respect to the gate electrode 4, i.e., each spacer is formed on one of the sidewalls 38 of the gate stack. Further, the second conductive layer 122 comprises, e.g., titanium nitride (TiN) as a midgap material, or tantalum nitride (TaN), which has a work function of about 4.0 eV.

The single layer gate stack shown in FIG. 2 has a capping layer 16, e.g., a silicon nitride, which covers both the single first conductive layer 102 and the second conductive spacer 122. This feature of capping layer 16 extending horizontally beyond the first conductive layer 102 provides an advantage in that the corresponding overhang protects the vertical spacer portion during the etching of the second conductive layer 122, particularly if an anisotropic etch is performed.

The overhang is formed by first depositing the first conductive layer 102 upon the gate dielectric layer 22, and then the isolating capping layer 16 is formed above (if there are further layers in the stack) or directly on top of the first conductive layer 102. Next, the anisotropic etch is performed to define the stack. Then, an isotropic etch is performed to recess the stack material of the first conductive layer below the isolating capping layer 16 in a horizontal direction, with a selectivity of the etch process of the conductive layer material as compared with the isolating capping material.

The second conductive layer 122 is further covered with a nitride liner 202, followed by an isolation spacer 32 of, e.g., silicon dioxide.

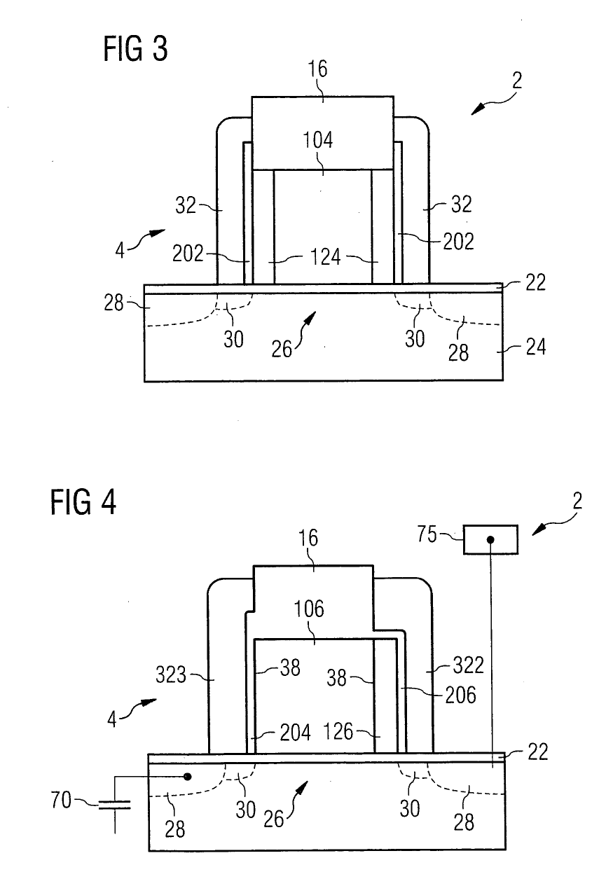

FIG. 3 shows a similar third embodiment as the second one indicated in FIG. 2 wherein, however, the first conductive layer 104 formed in the gate stack in a horizontal manner is a midgap material, while the second conductive material 124 of doped poly silicon is formed as a vertical spacer.

FIG. 4 illustrates a fourth embodiment wherein the second conductive layer 126 is formed as a single-sided vertical spacer. In this embodiment, the second conductive layer 126 is made of molybdenum, which has been implanted with nitrogen (i.e, Mo(N)). The first conductive layer 106 comprises n-doped poly silicon. Nitride liners 204, 206 cover the left sidewall 38 and the vertical spacer, respectively.

Also indicated is the connection of a first of the source/drain regions 28 with a storage node 70, and a second of the source/drain regions 28 with a sense amplifier 75. The sense amplifier in operation may apply a voltage to the respective source/drain region when reading out or writing in information from/to the storage node device, wherein the information is represented by charge carriers.

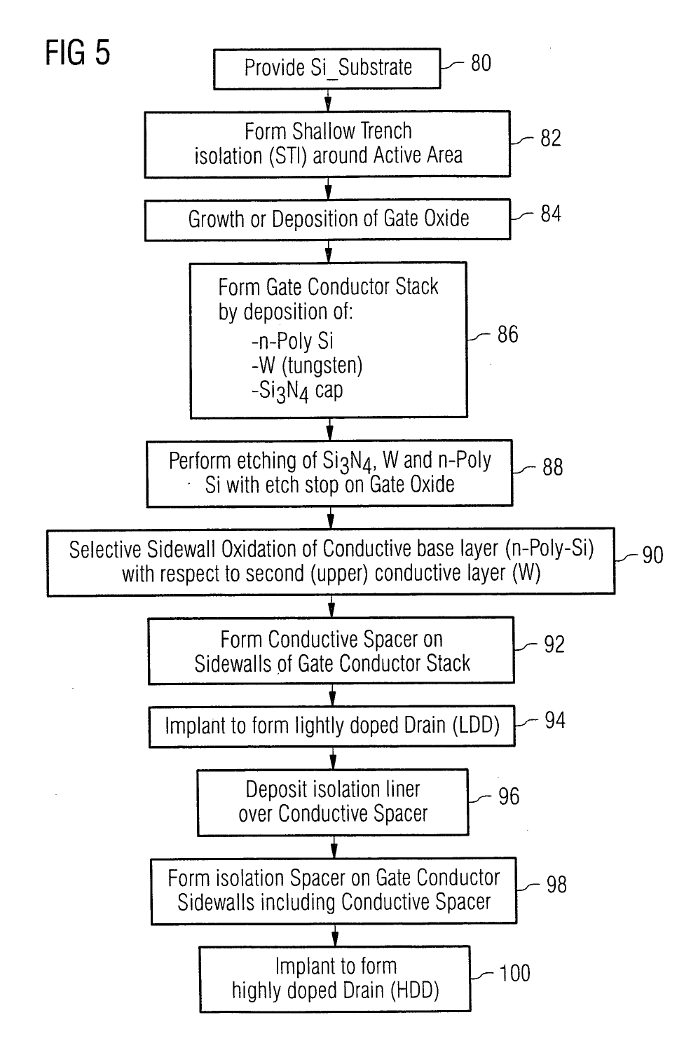

FIG. 5 shows a flow chart of the method according to an embodiment of the invention. A silicon substrate 24 is provided (step 80), wherein in a first lithographic step (step 82) an active area is formed by etching trenches in the substrate and filling the trenches with isolating material (shallow trench isolation, STI). A gate oxide is then deposited (step 84).

Layers 10, 14, 16 of poly silicon, tungsten and silicon nitride are sequentially deposited upon the gate oxide (step 86). A second lithographic step (88) is performed to structure the gate stack having a desired width of, e.g., 65-70 nm. Lithographic steps as referred to herein may comprise coating the substrate with a resist, exposing and developing the resist, removing portions of the resist and etching the stacked layers using the remaining resist as an etch mask.

In case tungsten is employed for the third conductive layer 14 and poly silicon is employed for the first conductive layer 10, an optional barrier layer of TiN or WN having a thickness of, e.g., 4-7 nm may be arranged between the first and third conductive layers.

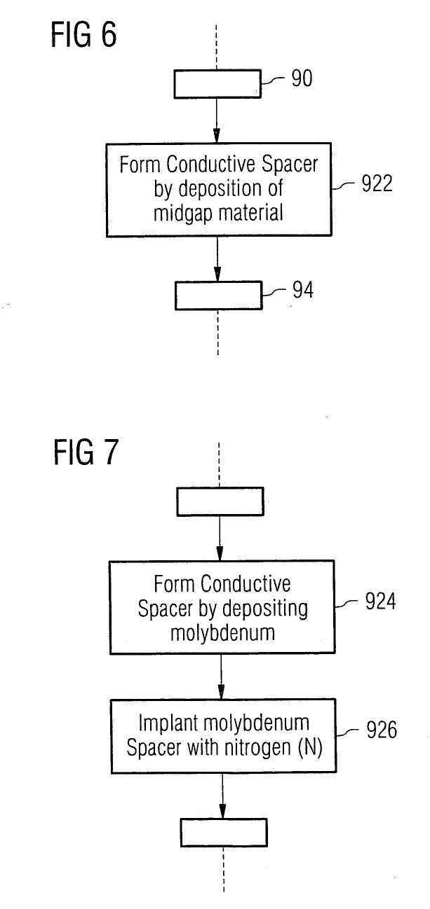

Next, the poly silicon portion of a resulting sidewall 38 of the gate stack is oxidized to yield a thin oxidation layer 18 (step 90). Adjacent to the sidewalls 38 and upon the oxidation layer 18 is formed a second conductive layer 12 of, e.g., a midgap material such as tungsten or tungsten silicide (step 92), see also FIG. 6, step 922, which depicts an alternative embodiment. The second conductive layer 12 thus formed further contacts the gate oxide, thereby extending the gate contact area. Herein, the second conductive layer 12 is conductively connected with the gate stack, e.g., with the (third) layer 14 of tungsten. The sidewall oxidation (step 90) is performed selectively and merely with respect to the (first) conductive layer 10 in this embodiment.

In one embodiment this layer 12 is first deposited and then exposed to an anisotropic etch process, wherein only vertical portions of the layer 12 are retained, thus yielding the vertical spacers.

In another embodiment, illustrated in FIG. 7, the second conductive layer 12 is formed by first depositing a layer of (undoped) amorphous silicon (step 924) followed by an anisotropic back etching as explained above. Then, an implant process of B, BF₂ or As (step 926) is applied using an oblique implantation angle. As a result only a single side of the gate electrode, i.e., only one of the two spacers is implanted, while the other spacer is shaded by the capping layer. Selectively removing the non-implanted spacer by means of an etch chemistry comprising NH₄(OH) then yields a single-sided spacer.

What is claimed is:

1. A field effect transistor disposed in a semiconductor substrate, comprising:
a first and a second doped source/drain region, both regions arranged within said substrate on either side of a gate electrode;
a channel region disposed within the substrate between both doped source/drain regions and beneath said gate electrode;
a gate oxide layer disposed upon the semiconductor substrate; and
the gate electrode, which contacts a surface of the gate oxide layer and which further comprises at least a first and a second conductive layer, said first and second conductive layers being made of materials having different work functions with respect to each other, wherein:
said first conductive layer of said gate electrode contacts said gate oxide layer within a first portion of the surface,
said second conductive layer contacts said gate oxide layer within a second portion of the surface, and
said first conductive layer is further conductively connected to said second conductive layer.

2. The transistor according to claim 1, wherein the first conductive layer comprises n-doped or p-doped poly silicon.

3. The transistor according to claim 1, wherein the second conductive layer comprises a material having work function of more than 4.0 eV and less than 5.3 eV.

4. The transistor according to claim 1, wherein the second conductive layer comprises a material having work function of more than 4.4 eV and less than 4.9 eV.

5. The transistor according to claim 1, wherein the second conductive layer comprises a material having work function of more than 4.5 eV and less than 4.8 eV.

6. The transistor according to claim 1, wherein the second conductive layer comprises a material selected from the group comprising of tungsten (W), titanium nitride (TiN), tungsten silicide (WSi₂), nitrogen implanted molybdenum (Mo(N)), tantalum nitride (TaN), molybdenum (Mo), tantalum (Ta), molybdenum silicide (MoSi₂), ruthenium (Ru), and combinations thereof.

7. The transistor according to claim 1, wherein the gate electrode further comprises a third conductive layer, which is disposed on said first conductive layer and provides an electrical connection between said first and said second conductive layers.

8. The transistor according to claim 7, wherein the gate electrode further comprises a sidewall oxide, which is disposed on a sidewall of the first conductive layer for separating the first and second conductive layers.

9. The transistor according to claim 7, wherein the second conductive layer is a vertical spacer with respect to a gate stack, which comprises the horizontally arranged layers of the first conductive layer and the third conductive layer.

10. The transistor according to claim 8, wherein the second conductive layer is a vertical spacer with respect to a gate stack, which comprises the horizontally arranged layers of the first conductive layer and the third conductive layer.

11. The transistor according to claim 9, wherein the gate stack further comprises an isolating capping layer.

12. The transistor according to claim 10, wherein the gate stack further comprises an isolating capping layer.

13. The transistor according to claim 11, wherein the isolating capping layer comprises an overhang, such that the capping layer covers the gate stack and said spacer with respect to an anisotropic etch process.

14. The transistor according to claim 12, wherein the isolating capping layer comprises an overhang, such that the capping layer covers the gate stack and said spacer with respect to an anisotropic etch process.

15. A field effect transistor disposed in a semiconductor substrate, comprising:
a first and a second doped source/drain region, both regions disposed within said substrate on either side of a gate electrode;
a channel region arranged within the semiconductor substrate between the highly doped source/drain regions and beneath said gate electrode;
a gate dielectric layer arranged upon the semiconductor substrate; and
the gate electrode, which contacts a surface of the gate dielectric layer and which further has a first layer of n-doped or p-doped poly silicon and at least one second layer of a conductive material, which has a work function of more than 4.0 eV and less than 5.3 eV, wherein:
the first layer contacts said gate dielectric layer within a first portion of the surface,
said at least one second layer contacts said gate dielectric layer within a second portion of the surface, and
said first layer is further conductively connected to said at least one second layer.

16. The transistor according to claim 15, wherein the gate electrode comprises a gate stack of layers, which are arranged in a horizontal manner one above the other, the gate stack comprising said first layer of n-doped or p-doped poly silicon, a third layer of a metal or a metal silicide disposed on the first layer and an isolating capping layer disposed on the third layer.

17. The transistor according to claim 16, wherein the metal of said third layer is tungsten, or the metal silicide of said third layer is tungsten silicide, and the isolating capping layer is a silicon nitride.

18. The transistor according to claim 15, wherein the at least one second layer of a conductive material, which contacts the surface of the gate dielectric layer, is a spacer, which is arranged in a vertical manner at a sidewall of said gate electrode.

19. A field effect transistor disposed in a semiconductor substrate, comprising:
a first and a second highly doped source/drain region, both regions arranged within said substrate on either side of a gate electrode;
a channel region arranged within the substrate between the highly doped source/drain regions and beneath said gate electrode;
a gate dielectric layer arranged upon the semiconductor substrate; and
the gate electrode, which contacts a surface of the gate dielectric layer and which further has a first layer of n-doped or p-doped poly silicon and at least one second layer of a conductive midgap material, which has a work function of more than 4.0 eV and of less than 5.3 eV, wherein:
the first layer is a horizontal layer, which contacts said gate dielectric layer within a first portion of the surface,
said at least one second layer is formed as a vertical spacer, which contacts said gate dielectric layer within a second portion of the surface, and
said first layer is further conductively connected to said at least one second layer.

20. The transistor according to claim 19, further comprising a third conductive layer of tungsten, or tungsten silicide, which is disposed upon said first layer of n-doped or p-doped poly silicon.

21. The transistor according to claim 20, further comprising a sidewall oxide, which is disposed on a vertical sidewall of said first horizontal layer adjacent to said vertical spacer of the at least one second layer, such that the first layer is conductively connected to the at least one second layer solely via the third conductive layer.

22. The transistor according to claim 19, further comprising each a lightly doped source and drain region adjacent to said gate dielectric layer, the channel region and said first or second source/drain region, respectively.

23. The transistor according to claim 19, wherein said at least one second layer of a conductive midgap material is arranged as a single sided vertical spacer, such that said transistor has an asymmetric profile.

24. A dynamic random access memory (DRAM) cell, comprising:
at least one second layer of a conductive midgap material arranged as a single-sided vertical spacer, such that a field effect transistor has an asymmetric profile;
a first and a second highly doped source/drain region, both regions arranged within a substrate on either side of a gate electrode;
a channel region arranged within the substrate between the highly doped source/drain regions and beneath said gate electrode;
a gate dielectric layer arranged upon the semiconductor substrate;
the gate electrode, which contacts a surface of the gate dielectric layer and which further has a first layer of n-doped or p-doped poly silicon and at least one second layer of a conductive midgap material, which has a work function of more than 4.0 eV and of less than 5.3 eV, wherein
the first layer is a horizontal layer, which contacts said gate dielectric layer within a first portion of the surface,
said at least one second layer is formed as a vertical spacer, which contacts said gate dielectric layer within a second portion of the surface, and
said first layer is further conductively connected to said at least one second layer; and
a storage node having a capacitor electrode, which is conductively connected to one of the first or second source/drain regions of the asymmetric transistor.

25. A method of forming a field effect transistor in a semiconductor substrate, comprising:
depositing a gate dielectric layer on a semiconductor substrate;
forming a first conductive layer of a material having a first work function upon said gate dielectric layer;
etching the first conductive layer to form a gate stack upon the gate dielectric layer;
forming a second conductive layer of a material having a second work function different from the first work function on a sidewall of the etched gate stack to form a conductive vertical spacer, said spacer and said gate stack forming a gate electrode; and
doping the semiconductor substrate on both sides of the gate electrode to form first and second source/drain regions.

26. The method according to claim 25, further comprising:
forming an isolating capping layer above the first conductive layer prior to etching the first conductive layer; and
forming the gate stack upon the gate dielectric layer by etching the isolating capping layer and at least the first conductive layer.

27. The method according to claim 26, further comprising performing an isotropic etch of the gate stack including a selectivity with respect to at least the first conductive layer such that the isolating capping layer above the first conductive layer forms an overhang with respect to the gate stack, said isotropic etch performed after said etching of the isolating capping layer and at least the first conductive layer.

28. The method according to claim 25, further comprising forming an isolation spacer on a sidewall of the gate electrode adjacent to the vertical conductive spacer, and etching the gate dielectric layer selectively with respect to said isolation spacer.

29. The method according to claim 25, further comprising depositing a third conductive layer after forming the first conductive layer and prior to depositing an isolating capping layer, wherein etching the first conductive layer and the isolating capping layer includes etching the third conductive layer.

30. The method according to claim 25, wherein forming the first conductive layer includes depositing a layer of poly silicon and simultaneously or subsequently n-doping or p-doping said layer with dopants.

31. The method according to claim 25, wherein forming the second conductive layer includes selecting a material having a work function of more than 4.0 eV and less than 5.3 eV.

32. The method according to claim 25, wherein forming the second conductive layer includes selecting a material having a work function of more than 4.4 eV and less than 4.9 eV.

33. The method according to claim 25, wherein forming the second conductive layer includes selecting a material having a work function of more than 4.5 eV and less than 4.8 eV.

34. The method according to claim 25, wherein forming the second conductive layer includes selecting a material from the group consisting of tungsten, tungsten silicide, titanium nitride, tantalum nitride, nitrogen implanted molybdenum, molybdenum, tantalum, ruthenium, molybdenum silicide, and combinations thereof.

35. A method of forming a field effect transistor in a semiconductor substrate, comprising:
depositing a gate oxide layer on a semiconductor substrate;
forming a first conductive layer of a material having a work function of more than 4.0 eV and less than 5.3 eV upon said gate dielectric layer;
etching the first conductive layer to form a gate stack upon the gate dielectric layer;
forming a second conductive layer of n-doped or p-doped poly silicon on a sidewall of the etched gate stack and on said gate oxide layer to form a conductive vertical spacer, said spacer and said gate stack forming a gate electrode of the transistor; and
implanting the semiconductor substrate where it is not shielded by said gate stack and said vertical conductive spacer to form first and second source/drain regions.

36. The method according to claim 35, wherein forming the first conductive layer includes selecting a material from the group consisting of tungsten, tungsten silicide, titanium nitride, tantalum nitride, nitrogen implanted molybdenum, molybdenum, tantalum, ruthenium, molybdenum silicide, and combinations thereof.

37. A method of forming a field effect transistor in a semiconductor substrate, comprising:
depositing a gate dielectric layer on a semiconductor substrate;
forming a first conductive layer of a material having a first work function upon said gate dielectric layer;
etching the first conductive layer to form a gate stack having two opposite sidewalls upon the gate dielectric layer;
depositing a second conductive layer of a material having a second work function on the gate stack and on the gate dielectric layer to form first and second conductive vertical spacers on opposite sidewalls of the gate stack, said spacers and said gate stack forming a gate electrode;
removing the first conductive vertical spacer formed on one of two opposite sidewalls of the gate stack to form an asymmetric gate electrode; and
implanting the semiconductor substrate where it is not shielded by said gate stack and said second vertical conductive spacer to form first and second source/drain regions.

38. The method according to claim 37, further comprising providing an isolating capping layer on top of the gate stack, or on top of the gate stack and the second conductive vertical spacer.

39. The method according to claim 37, wherein the first conductive vertical spacer is removed by implanting the gate electrode with dopants at an oblique angle, such that the first spacer is implanted and the second spacer is shaded by the isolating capping layer, and selectively etching the implanted first spacer with respect to the shaded second spacer.

40. The method according to claim 37, wherein the first conductive vertical spacer is removed by implanting the gate electrode with dopants at an oblique angle, such that the second spacer is implanted and the first spacer is shaded by the isolating capping layer, and selectively etching the shaded first spacer with respect to the implanted second spacer.
